(19) United States
(12) Patent Application Publication
(10) Pub. No.: US 2015/0189763 A1
(43) Pub. Date: Jul. 2, 2015

(54) Method for Embedding at Least One Component in a Printed Circuit Board

(71) Applicant: AT&S Austria Technologie & Systemtechnik Aktiengesellschaft, Leoben (AT)

(72) Inventor: Wolfgang Schrittwieser, Kapfenberg (AT)

(73) Assignee: AT&S Austria Technologie & Systemtechnik Aktiengesellschaft, Leoben (AT)

(21) Appl. No.: 14/412,594

(22) PCT Filed: Jun. 25, 2013
(86) PCT No.: PCT/AT2013/050128

§ 371 Date: Jan. 2, 2015

(30) Foreign Application Priority Data
Jul. 2, 2012 (AT) A 740/2012

(51) Int. Cl. H05K 3/30; H05K 3/20; H05K 3/08; H05K 1/18

(52) U.S. Cl. CPC H05K 3/305; H05K 1/186; H05K 3/202; H05K 3/08

(57) ABSTRACT

The invention relates to a method for embedding at least one component in a printed circuit board, comprising the steps of providing a lower metal conductor foil applied to a first metal supporting layer, forming recessed alignment marks in the conductor foil, applying an adhesive layer in a registered manner in relation to the alignment marks and fitting a component via the rear face thereof on the adhesive layer with upwardly pointing connection areas, curing the adhesive layer, embedding the component in an insulting layer, applying a metal upper conductor foil and an upper metal supporting layer, consolidating the structure, removing the supporting layers, exposing the alignment marks of the lower conductor foil by removing the insulating layer, producing cutouts ending at the lower conductor foil, producing bores to the connection areas of the component in a registered manner in relation to the alignment marks, and applying a conductor layer to the upper face of the structure, producing contact connections in the bores to the connection areas of the component, and structuring the conductor layer in order to produce conductive tracks.

The invention relates to a method for embedding at least one component in a printed circuit board, which is adhesively bonded with a lower conductor foil and whose connection areas point upwardly.

The invention also relates to a printed circuit board comprising at least one embedded component, which is adhesively bonded with a lower conductor foil and of which the connection areas point upwardly, said printed circuit board being produced in accordance with a method according to the invention.

A component, such as a chip, can be in principle embedded in a printed circuit board “face down” or “face up”. In the first case, the component side comprising contacts is connected to a metal conductor layer, as presented for example in WO 2012/016258 A2 in the name of the applicant, and in the latter case the component's reverse side is connected to the metal conductor layer, that is to say the adhesive bonding is implemented, as in a method of the type in question, on the side of the component facing away from the contacts. Methods of this type can be derived for example from WO 2007/087660 A1 and WO 2009/143550 A1 in the name of the applicant.

In the case of “face down” embedding methods, the moisture absorption of polyimide passivation layers often has an unfavourable influence on the quality of a printed circuit board module produced in this way. Specifically, the residual moisture remains on the underside of the component adhesively bonded on the metal conductor layer. Furthermore, cavities filled with air/gas and moisture are produced, for example by inhomogeneities of the adhesive, and remain once the adhesive has cured. Inhomogeneities of this type can adversely influence the reliable contacting of the components, which is implemented through the metal conductor layer. The above-mentioned document WO 2012/016258 A2 deals with this problem and proposes an attempt at a solution on the basis of a special adhesive and adhesive bonding method.

Since, in the case of “face up” embedding methods, the side of a component generally carrying no contacts is adhesively bonded with the metal conductor layer, the previously mentioned problems are overcome or are at least drastically reduced.

A further problem lies rather generally in the fact that the processing, in particular the application of adhesive areas and of components and also the (laser) drilling for the preparation of contact connections at the connections of components, in view of the small dimensions of the connection areas, can only be performed if the tools used are aligned with reference or alignment marks (also refereed to hereinafter generally as “marks”), or what are known as “fiducials”, which are mounted on generally metal conductor layers, in particular in the form of bores.

In the case of the above-mentioned “face down” embedding methods, such alignment marks are used initially for the fitting with components, that is to say the fitting machine is aligned from above with the marks and the components are applied from above onto the metal conductor layer. With the subsequent step of laser drilling for the contact connections of the component, the alignment marks are only detected from below in order to adjust accordingly the device for laser drilling, with which the metal conductor layer is drilled through from below. In this way, very high precision can be achieved with regard to the positioning of the bores. Such high precision is necessary in view of the extremely small dimensions of the connection areas (contact connections) of the components to be embedded.

By contrast, in the case of the known “face up” embedding methods, no direct reference is given between the fitting position of the printed circuit board and the contacting position of the component. Here, alignment marks are usually first detected from below for the fitting with components, and through-bores are then produced through the entire structure from below, upwardly. These through-bores serve as further alignment marks and are detected from above in order to be able to produce the contact bores to the connection areas of the components at the correct locations. In particular when producing the through-bores, the devices used here lead to inaccuracies, which have an adverse effect on the subsequently made contact connections. With such a method, inaccuracies in the region of ±60 μm are to be expected, which sets limits for a further miniaturisation.

One object of the invention is to increase the attainable accuracy when producing a printed circuit board with embedded components, without this resulting in a high outlay in terms of time and costs. A further object of the invention is to avoid the problems described in the introduction with the “face down” fitting or embedding.

This object is achieved with a method of the type mentioned in the introduction, which is characterised in accordance with the invention by the following steps:

providing a lower conductor foil, which is applied to a first metal supporting layer,

forming alignment marks at least in the conductor foil,

applying at least one adhesive layer in a registered manner in relation to the alignment marks, in order to fix at least one component,

fitting a component via the rear side thereof on the adhesive layer in a registered manner in relation to the alignment marks, wherein the connection areas of the component point upwardly, and curing the adhesive of the at least one adhesive layer,

embedding the component in an insulating layer,

applying a metal upper conductor foil and an upper metal supporting layer,

pressing and consolidating the entire structure,

removing the supporting layers,

exposing the alignment marks of the lower conductor foil by removing the insulating layer in the region of the alignment marks and producing corresponding cutouts,

producing bores, by means of a laser, to the connection areas of the component in a registered manner in relation to the alignment marks, and

applying a conductor layer to at least the upper side of the structure, producing contact connections in the bores to the connection areas of the component, and also structuring the conductor layer in order to produce conductive tracks.

Due to the invention, only a one-time alignment with alignment marks is necessary in the case of a face up embedding method, whereby, in contrast to the methods known in accordance with the prior art, considerably higher accuracies can be attained when producing the contact bores. Due to the direct relationship between fitting and contacting position, much higher accuracies can thus be attained than with conventional registration methods. Accuracies in the region of ±20 μm are actually provided.

In view of the use of an adhesive to secure the components, it is expedient if the lower and/or upper conductor foil is provided with an insulating coating, since the relatively rough surface of the conductor foils, which usually consist of copper, is covered by this coating. For example, what is known as the “bleeding” effect is thus avoided, in which solvent escapes from the adhesive and causes the adhesive to dry out.

In view of a cost-effective and proven production, it is expedient if the conductor foils and the supporting layers consist of copper.

Since laser drilling devices are usually also available for other drilling processes during the production process, it is advantageous if the alignment marks are formed by laser drilling. It has proven to be particularly successful if the laser drilling is carried out with the aid of a UV laser.

It is cost effective and has been proven to be successful in practice if the adhesive layer is applied by screen printing.

If in step d) outer edges and/or connection areas of the component are aligned, a particularly high accuracy in subsequent process steps is achieved.

In order to attain high packing densities, it is expedient if the component is formed as a thinned chip.

It has proven to be particularly expedient and cost-effective in practice if the insulating layer consists of a foil cut out in accordance with the at least one component and also of a continuous cover foil arranged thereabove.

For quick and reliable production and in order to avoid the continued presence of moisture residues, it is expedient if in step g) mechanical pressure, increased temperature and also negative pressure (vacuum) is applied to the structure.

The precision with regard to the bore depth required during production of the cutouts can be achieved particularly easily if in step i) the cutouts are produced with the aid of picosecond laser drilling technology.

It has proven to be advantageous if, when producing the bores in step j), the upper conductor foil is firstly removed in a first sub-step using a UV laser and then in a second sub-step the layer is removed as far as the connection areas of the components by means of a CO₂ laser.

On the other hand, the equipment outlay in the case of application of the method can be reduced if in step j) the bores are produced in a single process step with the aid of picosecond laser drilling technology.

A printed circuit board comprising at least one embedded component, which is secured on a lower conductor foil by adhesive bonding and of which the connection areas point upwardly, said printed circuit board being produced by a method according to the invention, is characterised by a high reliability with very high packing density.

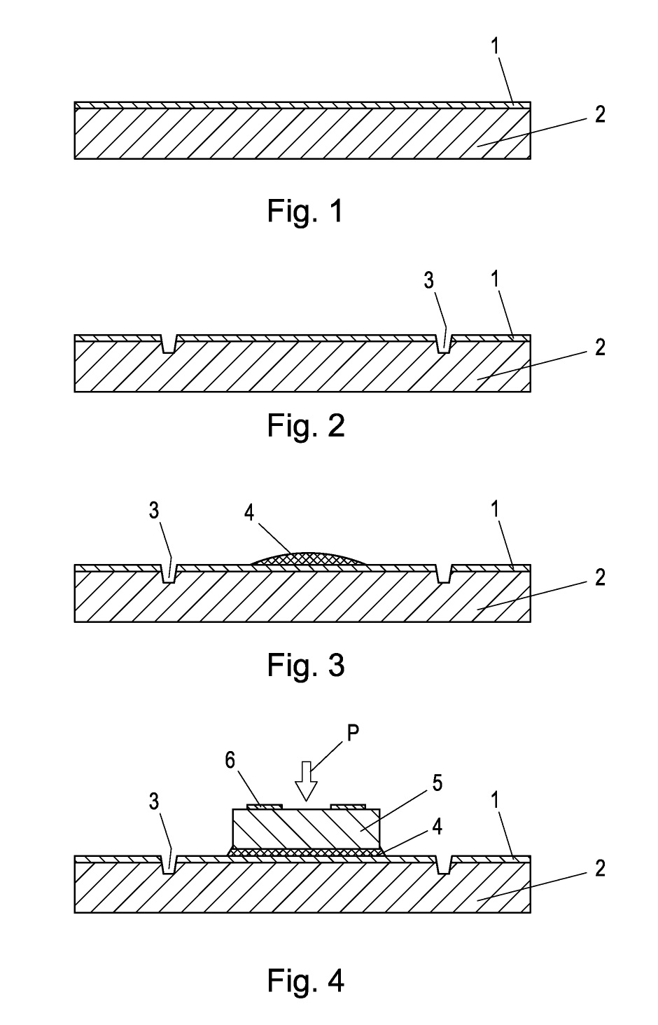

The invention and further advantages will be explained in greater detail hereinafter with reference to exemplary embodiments, which are illustrated in the drawing. In the drawing, FIGS. 1 to 10 show the individual method steps of the invention for constructing a printed circuit board structure comprising at least one component, in each case in schematic sectional views of part of a printed circuit board.

With reference to FIGS. 1 to 10, the method according to the invention for producing a printed circuit board comprising at least one integrated component or such a printed circuit board according to the invention will now be described.

FIG. 1 shows the first step of the method, specifically the provision of a thin lower conductor foil 1, for example a 2 μm Cu foil, which is supported on a thicker lower supporting layer 2, for example a 70 μm Cu foil, wherein the layers 1 and 2 are interconnected. The combination of lower conductor foil/supporting layer can also have an insulating coating (not shown here), for example a resin layer, which is applied on the upper side, that is to say on the conductor foil 1, and which is for example 5 to 15 μm thick. Due to such a coating, the relatively rough surface of the conductor foils, which usually consist of copper, is covered, which has proven to be expedient when securing the components by means of an adhesive.

In particular, by means of such a layer, which is smooth compared to copper, what is known as the “bleeding” effect, that is to say the escape of the solvent from the adhesive and the resultant drying out of the adhesive, is reduced.

In the next step according to FIG. 2, alignment marks 3, or what known as fiducials, are drilled by means of a laser, preferably a UV laser, into the lower conductor foil 1 and through said conductor foil also into the supporting layer 2. Such alignment marks enable the alignment (registration) of the printed circuit board with respect to any tools which are required later for further production or processing of the printed circuit board and which for example apply adhesive by means of screen printing, fit components, or are used to produce bores by means of laser. At least four such alignment marks are generally required, however the exact number and configuration thereof can or must be selected individually.

Now, as illustrated in FIG. 3, adhesive layers 4 for fastening components are applied to the lower conductor foil 1, for example by roll coating or a printing method, in particular a screen printing method, as described for example in WO 2007/087660 A1 and WO 2009/143550 A1 in the name of the applicant. Following the application of the adhesive layers 4, a vacuum treatment can also be performed in order to remove air from the adhesive used.

Then, see FIG. 4, a component 5, for example what is known as a “thinned” chip, that is to say a chip that is for example ground to a size of 50 to 200 μm in thickness, is arranged via the rear face thereof on the lower conductor foil 1 in the region of the adhesive layer 4 by a fitting machine aligned with the alignment marks 3. Here, the outer edges and conductive connection areas 6 of the component 5 are aligned. Generally, a number of components 5 are of course applied simultaneously to the metal conductor layer 1. The adhesive of the adhesive layer or adhesive layers 4 can now be cured in a known manner, in particular thermally. An arrow P in FIG. 4 is intended to indicate the application of a certain contact pressure.

Due to the thermal curing and/or the deaeration of the adhesive, the above-mentioned problem of air and/or moisture inclusion in the adhesive is also overcome.

Besides chips, which contain highly integrated circuits, other components used in electronics can also be used as components, for example resistors, capacitors, etc.

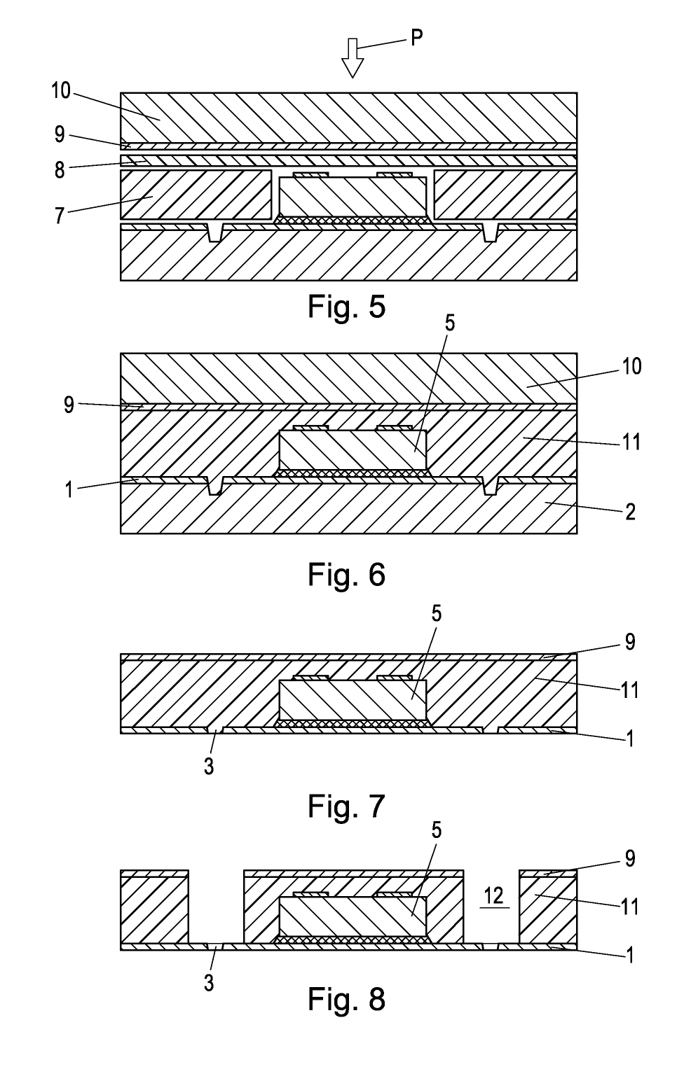

Following the application of the component 5, said component is actually embedded by applying a cut-out foil 7 and also a cover foil 8, wherein reference is now made to FIG. 5. In this example, an FR4 foil (a glass fibre mat impregnated with epoxy resin) is applied as cut-out foil 7 in a thickness which exceeds the height of the component inclusive of the thickness of the adhesive layer 4, such that a pressure relief of the component 5 is ensured during subsequent pressing processes. In order to homogeneously fill out the cavities between the fitted component 5 and the cut-out foil 7, the cover foil 8, which is not cut out, is placed over the structure already provided. An upper conductor foil 9, in particular a Cu foil, inclusive of an upper supporting layer 10 arranged thereon, which likewise may be formed as a Cu foil, then follows on the cover foil 8. Similarly to the lower conductor foil 1, the upper conductor foil 9 may have an insulating coating on the side thereof facing the component 5. The layers or foils 1, 2 and 9, 10 are arranged in a mirror-inverted manner relative to one another. The structure is then pressed with application of mechanical pressure, temperature and negative pressure (vacuum), which is again indicated by an arrow P.

FIG. 6 shows the result of the aforementioned pressing, wherein it can be noted that the alignment marks 3 now also are no longer “visible”. The films 7 and 8 now form a practically integral insulating layer 11, which also fills out the alignment marks 3.

In a next step, the lower and the upper supporting layer 2 and 10 are removed, preferably by simply being pulled off, whereby the structure shown in FIG. 7 is obtained.

In a further step, see FIG. 8, the alignment marks 3 present in the lower conductor foil 1, can now be exposed such that they are “visible” from above. For this purpose, the upper conductor foil 9 and the underlying insulating layer 11 (FR4 foils) are removed in the region of the alignment marks 3 as far as the lower conductor foil 1, which has to remain, however, such that cutouts 12 are produced. Here, the low thickness of this conductor foil 1, in the example a 2 μm Cu foil, is problematic, and it has been found in tests that an ultra-short pulse laser, in particular a picosecond laser, is the means of choice in order to perform this process. In fact, with shorter pulse length, less material is removed with one pulse, whereby a very good depth control can be achieved.

With use of a picosecond laser, thermal effects can also be reduced to the extent that there is no carbonation of the FR4 material.

With such a commercially available laser the removal of the material can be stopped actually at, or immediately above the thin conductor foil 1 due to the short pulse length, such that the alignment marks 3 are retained. This depth control can be further promoted by the above-mentioned application of insulating coatings having different removal properties compared to the material arranged thereabove. As can be seen in FIG. 8, the produced cutouts 12 are significantly broader, that is to say generally have a greater diameter than the alignment marks 3, such that excessive demands are not placed on the alignment of the used picosecond laser.

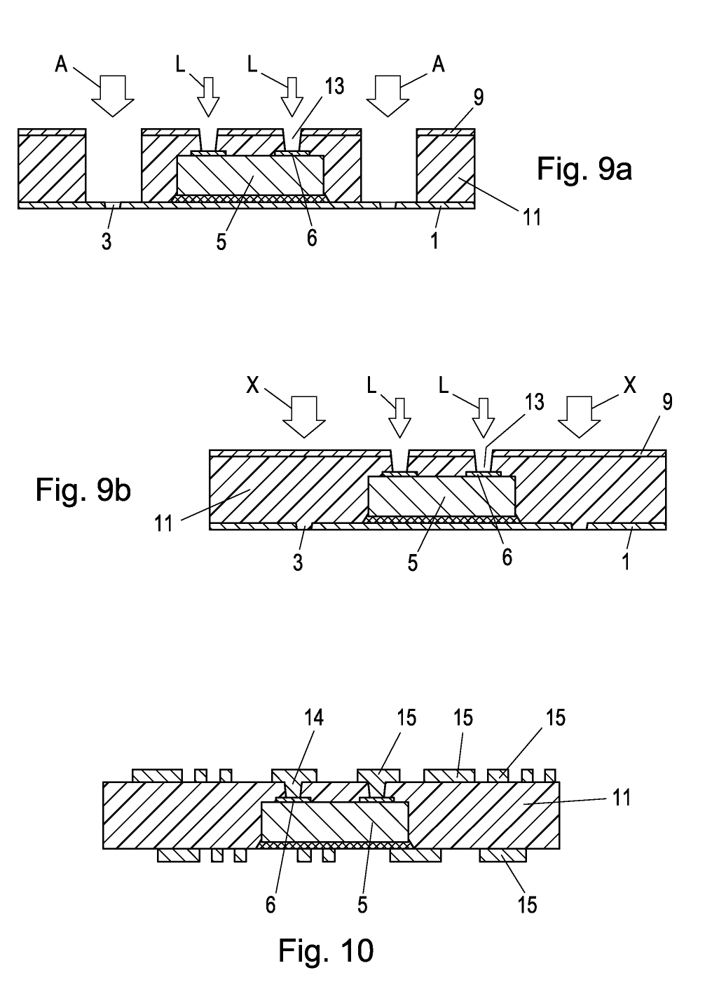

As soon as the alignment marks 3 are exposed, they can be used for the precise optical alignment of the devices for the following process steps, schematically depicted with arrows A in FIG. 9a, which represent the “viewing direction” of the alignment optics. It should be noted at this juncture that it may also be sufficient to “optically” expose the alignment marks, that is to say to remove material with the picosecond laser only until a thin layer of the FR4 material measuring a few micrometres thick still remains above the alignment marks 3, said layer being optically permeable, such that the marks can be detected through this layer by the cameras used. The term “expose the alignment marks” is thus to be understood in the sense that this exposure is performed at least until an optical detection of these marks is enabled.

Following the precise alignment, bores 13 can be produced with the aid for example of a CO₂ laser (arrows L) in order to prepare the contact connection. Since these bores 13 are produced with very accurate alignment, small connection areas 6 can also be contacted with certainty, and therefore many connections 6 on very small components 5 are also possible.

In practice, it has proven to be favourable to apply a combined method when producing the bores 13, in which method the layer 9, which usually consists of copper, is firstly removed with a defined diameter by means of a UV laser, that is to say the bore is “opened”, and the FR4 material of the layer 11 is then removed by means of a CO₂ laser as far as the connection areas 6 of the components 5.

An alternative possibility for producing the bores 13 lies in producing these bores in a single process step with the aid of a picosecond laser that was also used previously in order to expose the alignment marks 3. In this way, the use of different laser systems when carrying out the method according to the invention is spared.

In accordance with FIG. 10, contact connections 14 are produced in the bores 13 by galvanic application of copper on both sides and by structuring the upper and lower copper layers, for example by means of a photolithographic method in order to produce conductive tracks 15. Of course, through-contact connections could also be produced between upper and lower conductive tracks.

Alternatively to the exposure of the alignment marks 3, it is also possible for the optical detection thereof to perform the alignment by means of X-rays, which is illustrated in FIG. 9b by arrows X. Then, a suitable radiation source has to be used on one side of the printed circuit board arrangement with corresponding image recording systems on the opposite side. However, in order to obtain a sufficiently high contrast in this case, the lower conductor layer 1, provided it consists of copper, should be thicker than 5 μm.

### LIST OF REFERENCE SIGNS (not part of the application)

1 lower conductor foil
2 lower supporting layer
3 alignment mark
4 adhesive layer
5 component
6 connection areas
7 foil
8 cover foil
9 upper conductor foil
10 upper supporting layer
11 insulating layer
12 cutouts
13 bores
14 contact connections
15 conductive tracks
A arrow
L arrow
P arrow
X arrow

1. A method for embedding in a printed circuit board at least one component, which is secured on a lower conductor foil by adhesive bonding and of which the connection areas point upwardly, comprising:
a) providing a lower conductor foil, which is applied to a first metal supporting layer,
b) forming alignment marks at least in the conductor foil,
c) applying at least one adhesive layer in a registered manner in relation to the alignment marks, in order to fix at least one component,
d) fitting a component via the rear side thereof on the adhesive layer in a registered manner in relation to the alignment marks, wherein the connection areas of the component point upwardly, and curing the adhesive of the at least one adhesive layer,
e) embedding the component in an insulating layer,
f) applying a metal upper conductor foil and an upper metal supporting layer,
g) pressing and consolidating the entire structure,
h) removing the supporting layers,
i) exposing the alignment marks of the lower conductor foil by removing the insulating layer in the region of the alignment marks and producing corresponding cutouts,
j) producing bores, by means of laser, to the connection areas of the component in a registered manner in relation to the alignments marks, and
k) applying a conductor layer at least to the upper side of the structure, producing contact connections in the bores to the connection areas of the component, and also structuring the conductor layer in order to produce conductive tracks.

2. The method according to claim 1, characterised in that the lower and/or upper conductor foil is provided with an insulating coating.

3. The method according to claim 1, characterised in that the conductor foils and the supporting layers consist of copper.

4. The method according to claim 1, characterised in that in step b) the alignment marks are formed by laser drilling.

5. The method according to claim 4 characterised in that step b) the laser drilling is performed with the aid of a UV laser.

6. The method according to claim 1, characterised in that in step c) the adhesive layer is applied by screen printing.

7. The method according to claim 1, characterised in that in step d) outer edges and/or connection areas of the component are aligned.

8. The method according to claim 1, characterised in that the component is formed as a thinned chip.

9. The method according to claim 1, characterised in that the insulating layer consists of a foil cut out in accordance with the at least one component and also of a continuous cover foil arranged above the foil.

10. The method according to claim 1, characterised in that in step g) mechanical pressure, increased temperature and negative pressure are applied to the structure.

11. The method according to claim 1, characterised in that in step i) the cutouts are produced with the aid of picosecond laser drilling technology.

12. The method according to claim 1, characterised in that, when producing the bores in step j), the upper conductor foil is first removed in a first sub-step using a UV laser and then in a second sub-step the layer is removed as far as the connection areas of the components by means of a CO2 laser.

13. The method according to claim 1, characterised in that in step j) the bores are produced in a single process step with the aid of picosecond laser drilling technology.

14. A printed circuit board comprising at least one embedded component, which is fastened on a lower conductor foil by adhesive bonding and of which the connection areas point upwardly, said printed circuit board being produced by a method according to claim 1.
